(19) United States
(12) Patent Application Publication
(10) Pub. No.: US 2025/0173486 A1
(43) Pub. Date: May 29, 2025

(54) SYSTEM AND METHOD FOR WILDFIRE IGNITION MODELING

(71) Applicant: University of Connecticut, Farmington, CT (US)

(72) Inventors: Diego Cerrai, Stafford Springs, CT (US); Sita Nyame, Hartford, CT (US); William Taylor, Simsbury, CT (US); Aaron Spaulding, Windsor, CT (US); Marika Koukoula, Lausanne (CH); Feifei Yang, Lakeville, MN (US); Emmanouil Anagnostou, Mansfield Center, CT (US)

(21) Appl. No.: 18/962,608

(22) Filed: Nov. 27, 2024

Related U.S. Application Data
(60) Provisional application No. 63/603,311, filed on Nov. 28, 2023.

(51) Int. Cl. G06F 30/27; G08B 17/00

(52) U.S. Cl. CPC G06F 30/27; G08B 17/005

(57) ABSTRACT

A system for at least one of warning of a possible wildfire or preventing a wildfire ignition in a selected area of interest includes a processor configured to execute instructions stored on a non-transitory medium. The instructions include receiving input data related to conditions that are relevant to igniting a wildfire in the selected area of interest. The instructions also include creating a model of a possible wildfire ignition in the selected area of interest using an artificial intelligence algorithm that is trained with the input data, providing an output from the model related to the possible wildfire ignition, and transmitting an alert notification automatically in response to the output exceeding a selected threshold value. The system also includes at least one of a warning device or a wildfire ignition prevention device configured to be automatically activated in response to receiving the alert notification.

### BACKGROUND OF THE INVENTION

### 1. Field of the Invention

The invention disclosed herein relates to a computerized framework for predicting locations where ignition of a wildfire may occur and for implementing actions to prevent, mitigate, or warn of the ignition.

### 2. Description of the Related Art

Currently, it is difficult to predict where and when wildfires will occur. A host of factors are responsible for triggering wildfires, including human activities, weather, environmental conditions, and infrastructure. If wildfires are detected quickly, it is possible to limit their extent and the damage they produce. When they are not limited, they can devastate entire ecosystems. Wildfires can be prevented through wildfire mitigation practices. Fuel management activities are one strategy to reduce the amount of vegetation that can burn. Another practice calls for Public Safety Power Shutoffs (PSPS), which involves turning off power to utility customers to prevent fires. Yet, the lack of predictability of wildfire ignitions prevents the implementation of targeted wildfire mitigation practices. This can result in, for example, an excessive extent of PSPS, or in a lack of adequate mitigation activities in high risk locations at some times.

What is needed is a solution for predicting wildfire ignition occurrences and probabilities at different spatial and temporal scales, and by ignition cause, in advance of their occurrence.

### SUMMARY

Disclosed is a system for at least one of warning of a possible wildfire or preventing a wildfire ignition in a selected area of interest includes a processor configured to execute instructions stored on a non-transitory medium. The instructions implement a method that includes receiving input data related to conditions that are relevant to igniting a wildfire in the selected area of interest, creating a model of a possible wildfire ignition in the selected area of interest using an artificial intelligence algorithm that is trained with the input data, providing an output from the model related to the possible wildfire ignition, and transmitting an alert notification automatically in response to the output exceeding a selected threshold value. The system also includes at least one of a warning device or a wildfire ignition prevention device configured to be automatically activated in response to receiving the alert notification.

Also disclosed is a non-transitory computer-readable medium having instructions for at least one of warning of a possible wildfire or preventing a wildfire ignition in a selected area of interest that when executed by a processor implements a method. The method includes receiving input data related to conditions that are relevant to igniting a wildfire in the selected area of interest, creating a model of a possible wildfire ignition in the selected area of interest using an artificial intelligence algorithm that is trained with the input data, providing an output from the model related to the possible wildfire ignition, and transmitting an alert notification to at least one of a warning device or a wildfire ignition prevention device in response to the output exceeding a selected threshold value. The at least one of the warning device and the wildfire ignition prevention device is configured to be automatically activated in response to receiving the alert notification.

Further disclosed is a system for at least one of warning of a possible wildfire or preventing a wildfire ignition in a selected area of interest. The system includes a processor configured to execute instructions stored on a non-transitory medium. The instructions implement a method that includes receiving input data related to conditions that are relevant to igniting a wildfire in the selected area of interest, creating a model of a possible wildfire ignition in the selected area of interest using an artificial intelligence algorithm that is trained with the input data, providing an output from the model related to the possible wildfire ignition, the output comprising a visualization of output data, and transmitting an alert notification in response to the output exceeding a selected threshold value. The system also includes a sensor in communication with the processor and disposed in the selected area of interest wherein the sensor is configured to sense an environmental parameter. The system further includes at least one of a warning device or a wildfire ignition prevention device configured to be automatically activated in response to receiving the alert notification.

### BRIEF DESCRIPTION OF THE DRAWINGS

The following descriptions should not be considered limiting in any way. With reference to the accompanying drawings, like elements are numbered alike:

FIG. 1 illustrates an exemplary embodiment of system components for implementing a wildfire ignition prediction, prevention and mitigation system;

FIG. 2 illustrates an exemplary embodiment of software architecture for the wildfire ignition, prevention and mitigation system;

FIG. 3 is an example of tabulated output data;

FIG. 4 is an example of a time-series representation of historical wildfire in a specific area of interest;

FIG. 5 is an example of a time-series prediction of historical wildfire in a specific area of interest;

FIG. 6A and 6B, collectively referred to as FIG. 6, depict aspects of sample maps of predicted and actual wildfires by county aggregated over a year;

FIG. 7 is a sample map of a predicted number of wildfire ignitions on a regular grid;

FIG. 8 depicts aspects of interactions between various software modules to produce wildfire ignition predictions; and

FIG. 9 is a flowchart for a method for performing measures to prevent or mitigate effects of the wildfire.

### DESCRIPTION OF THE INVENTION

Disclosed herein is a computerized framework for assessing the probability of ignition of a wildfire. Implementation of the framework enables users to mitigate risk by providing an assessment of contributing factors to wildfire risk and/or by providing predictions that highlight areas of high wildfire ignition risk, so that activities can be conducted to reduce that risk. Generally, the framework includes of (i) collecting input data, (ii) processing input data, (iii) generating predictions, (iv) populating resources such as through uploading to the Internet, and (v) performing notifications.

Generally, with regards to the foregoing: input data are related to the factors responsible for or related to wildfire ignitions; processing of the input data occurs through computerized models; output data includes predictions for ignition of a wildfire. The predictions may be uploaded to the Internet or shared through one or more other communication channels. In some embodiments, interested parties and stakeholders are notified through an alerting system. The term “model” and the like generally relates to a mathematical representation of a process by which a wildfire is ignited. The model can provide wildfire ignition predictions and other output related to ignition of wildfires.

Generally, the term “prediction” refers to assessing probability for a given scenario or estimating the expected number of fires occurring in a specific area over a specific time frame. It should be assumed that users will work to mitigate risk for higher probability situations, and therefore eliminate or address a potential outbreak of a wildfire. Thus, a prediction is not necessarily referred to an actual ignition but indicates risk. To be clear, even if no mitigation is performed, there is a chance that no fire occurs, even in locations assigned a high probability of ignition.

Generally, the term “wildland fire” or “wildfire” for short as used herein refers to unplanned and/or unsupervised combustion of ambient environmental materials such as brush, grasses, fallen trees, refuse, structures and other such fuels.

Generally, the framework may include a number of interface connections. For example, the framework may include: a number of application program interfaces (API) adapted for data exchange with other systems (such as grid related systems, and the Emergency Alert System (EAS)); user input and output screens adapted for large screens (such as in a control room or emergency operations center (EOC)), a personal computer, or a mobile interface such as a smart phone or tablet. Notifications may be performed through an alerting system, through mass communications in a privileged or public network and/or through other appropriate techniques.

Wildfire ignition predictions include but are not limited to predictions of wildfire ignition occurrences and probabilities at different spatial and temporal resolutions and scales. Predictions include but are not limited to nowcasting, short-range forecasts, medium-range forecasts, long-range forecasts, historical events predictions, analysis or re-analysis, assessment of change in wildfire risk through climate predictions climate predictions, and effectiveness of past, current, or planned wildfire mitigation practices. Predictions can be further classified by ignition causes, including but not limited to power lines, structures, railroads, smoking, arson, human, equipment, campfire, debris burning, lightning, or miscellaneous. The output can be saved and shared in various formats, including but not limited to data files, images, maps, time series, and videos.

In one embodiment, predictions are uploaded to the internet through a network interface. In other embodiments, the predictions are shared with relevant stakeholders and the media, through several forms, including but not limited to printed copies, text or multimedia messages, hardware devices, or software packages.

The alerting system may include a framework that alerts relevant stakeholders through one or more means of communication, including verbal, written, screen-oriented, or document transport. In one embodiment, a link to a website or an app is sent via a text or multimedia message or an email.

In one embodiment, the user interface includes a website or an app that can be seen through a screen and that allows users to visualize, analyze, and interact with the predictions at different temporal and spatial scales.

In some embodiments, systems, APIs, and other computer program products are developed using conventional tools such as Python, C++, a number of tools from Microsoft Corporation and other similar development tools.

In some embodiments, at least one interface screen is implemented through a browser.

Input resources may include live data such as from the National Weather Service (NWS), grid information such as from any one or more of a number of grid operators (such as Convex, ISO New England, the Eastern interconnection, the Western interconnection, and others), data from the US Forest Service (such as may be available from the USDA Forest Service Geodata Clearinghouse) and any state-based equivalents thereof, traffic monitoring and management systems, state and/or federal police fire and rescue resources and a number of other public or private resources. Other input resources may include historical data descriptive of similar entities and concerns.

Having introduced aspects of the framework, some additional features and embodiments are now disclosed.

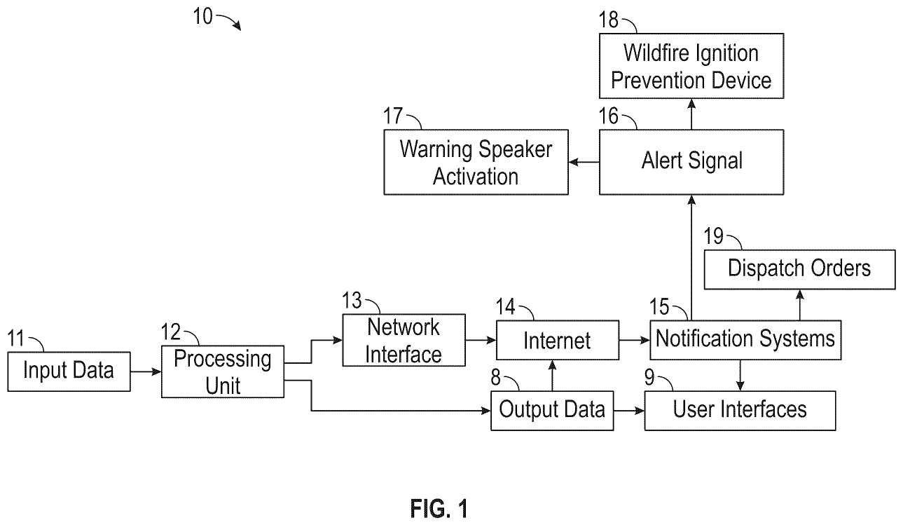

FIG. 1 illustrates an exemplary embodiment of system components for implementing a wildfire ignition risk prediction, prevention and mitigation system 10 (or wildfire system 10 for brevity). The wildfire system 10 includes a processing unit 12, which can be a computer processing system. In general, the processing unit 12 includes those components that may be present in a computer processing system such as a central processing unit, an accelerator, transitory and non-transitory memory, and input and output interfaces. The central processing unit is configured to implement artificial intelligence (AI) algorithms, machine-learning algorithms, and any of the algorithms disclosed herein. An input interface of the processing unit 12 receives input data 11 that is necessary for the processing that is used to predict risk of wildfires or prevent or mitigate wildfires. The input data may be input manually or downloaded from one or more sources such as through the Internet. The input data can be used for training the AI or machine-learning algorithms to obtain desired outputs. The processing unit 12 also includes an output interface for providing information or data to a network interface 13 which can interface with the Internet 14 for communicating the information or data via the Internet 14 to selected parties of interest. The information or data communicated via the Internet 14 may be provided to notification systems 15.

The notification systems 15 are configured to notify one or more parties of interest of a high risk of wildfire at a certain location. In one or more embodiments, the notification is an alert signal 16 that is automatically sent to the one or more parties of interest in response to the risk of wildfire at the certain location exceeding a threshold value. In one or more embodiments, the alert signal 16 automatically triggers activation of a warning speaker or siren 17 that can warn residents or the populace in an area of the certain location of the risk of a wildfire ignition. In one or more embodiments, the alert signal 16 automatically triggers activation of a wildfire ignition prevention device 18 such as a remote-controlled disconnect switch for disconnecting electrical power to the location having the risk of wildfire exceeding the threshold value. Other types of remote-controlled devices for preventing ignition of a wildfire may also be used.

The output interface of the processing unit 12 may also provide output data 8 to user interfaces 9 which can include a visual display, a printer, or a data storage system such as cloud storage. The output data 8 can be routine and sent on a selected periodic schedule such as once a day in an exemplary embodiment.

Input data may include but are not limited to historical, current, real-time, and future data related to weather, climate, environmental, elevation, surface property, vegetation, human factor, infrastructure, recreational activity, historical power outages, fuel and fire data.

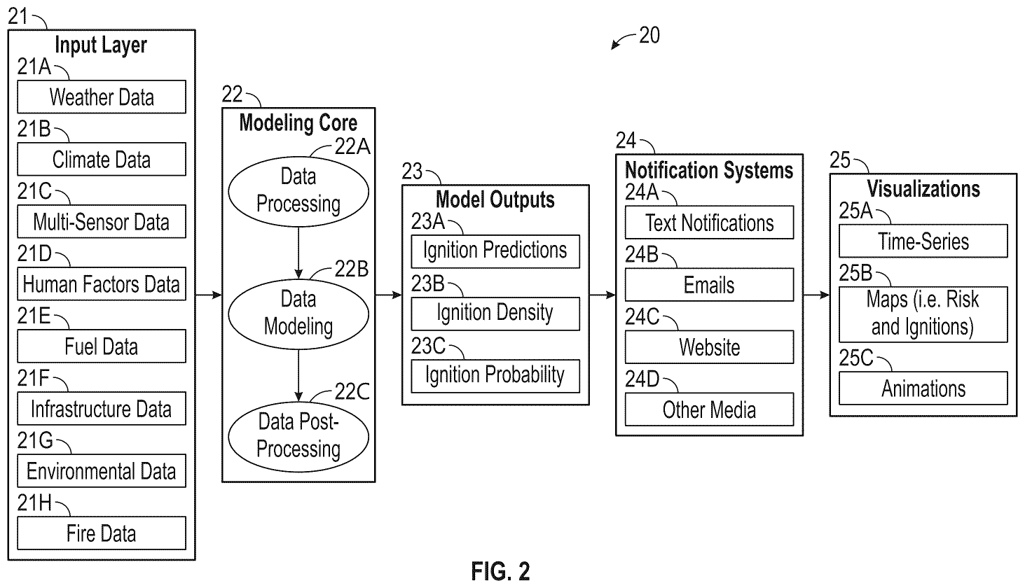

FIG. 2 illustrates an exemplary embodiment of wildfire ignition, prevention and mitigation system software architecture 20 (also referred to as wildfire software architecture 20 for brevity) for the wildfire ignition, prevention and mitigation system 10. The wildfire software architecture 20 includes an input layer 21 for inputting various types of data into a modeling core 22. Non-limiting embodiments of the various types of input data 21 include weather data 21A, climate data 21B, multi-sensor data 21C, human factors data 21D, fuel data 21E, infrastructure data 21F, environmental data 21G, and fire data 21H.

The weather data 21A can be extracted from ERA5-Land, a reanalysis dataset created through the combination of historical observations with atmospheric models using data assimilation by the European Center for Medium-Range Weather Forecasts (ECMWF). It provides a global, high-resolution dataset on detailed weather and climate data focused on land surfaces on an hourly basis at a 9-km spatial resolution. Weather data extracted include but are not limited to temperature, specific humidity, precipitation, wind, wind gust and soil moisture conditions. In one or more embodiments for each weather variable, the mean and maximum temporal values are extracted and can be denoted by the prefix “MEAN” and “MAX” respectively. Other forecasting, analysis, or reanalysis products can also be used such as GFS and Real-Time Mesoscale Analysis (RTMA) to obtain the weather data 21A.

The climate data 21B relates to long-term precipitation anomalies, drought indices, or other data related to long-term atmospheric patterns and can be obtained from various known sources as it is used to document climate change.

The multi-sensor data 21C relates to data obtained from sensors disposed in an area of interest that pertains to the probability of wildfire ignition. In one or more embodiments, multi-sensor data is collected from sensors installed on power lines to monitor key environmental parameters, including temperature, relative humidity, solar radiation, dew point temperature, and nearby smoke, providing historical information or early warning of fire hazards. This data can also be obtained from weather radar, LIDAR, or satellite data. Data from these sensors can be transmitted by wired or wireless communication or it can be downloaded locally.

The human factors data 21D may include population density data can be collected from NASA NEO Population Density at a one square kilometer resolution to represent the number of people living in each specific location. Real time population density data in real time can be obtained from Google Places. Population density data can also be obtained from US Census Bureau Population or United Nations.

The fuel data 21E relates to fuel density is a selected area of interest. The fuel data may include the type of fuel, the BTU content of the fuel, the ease of igniting the fuel, and the ability of the fuel or fire to spread by wind in non-limiting embodiments. The primary fuel data used can be from the 13 Anderson Fire Behavior Fuel Models which form a standardized system to classify various types of wildland fuels based on their potential fire behavior extracted from LANDFIRE 2022. Each of the 13 fuel models represents a distinct type of vegetation and fire potential. These models describe how fire spreads through the fuels, based on factors like fuel load, moisture, and size of the vegetation. The fire behavior fuel models can be aggregated into four main classes based on geographical knowledge to best capture the possibility of fire ignitions. The four classes are aggregated as follows: (1) Herbaceous Fuel—Summation of FBFM1 (surface fires that burn fine herbaceous fuels), FBFM2 (burns fine, herbaceous fuels), FBFM3 (most intense fire of grass group, spreads quickly with wind); (2)—Shrubs Fuel—Summation of FBFM4 (fast spreading fire, continuous overstory, flammable foliage and dead woody material), FBFM5 (low intensity fires, young, green shrubs with little dead material), FBFM6 (broad range of shrubs, fire requires moderate winds to maintain flame at shrub height), FBFM7 (foliage highly flammable, allowing fire to reach shrub strata levels); (3) Closed Canopy Fuel—Summation of FBFM8 (slow, ground burning fires, closed canopy stands with short needle conifers or hardwoods), FBFM9 (longer flames, quicker surface fires, closed canopy stand of long-needles or hardwoods); and (4) High Fuel—Summation of FBFM10 (surface and ground fire more intense, dead-down fuels more abundant), FBFM11 (fairly active fire, fuels consist of slash and herbaceous materials), FBFM12 (rapid spreading and high intensity fires, dominated by slash resulting from heavy thinning projects and clearcuts), FBFM13 (fire spreads quickly through smaller material and intensity builds slowly as large material ignites). The fuel data 21E may also be obtained from 40 Scott and Burgan Fire Behavior Fuel Models. The fuel data 21E may also include areas having no fuel. In one or more embodiments, the No Fuel Areas are a summation of water areas, barren land areas, and snow/ice areas.

Vegetation can be a source of fuel. Hence, the fuel data 21E may also include vegetation data, which can include existing vegetation type, existing vegetation height, and leaf area index. Vegetation type data can be extracted from the LANDFIRE 2022 Existing Vegetation Type (EVT) dataset, describing the various groups of plant communities that typically grow together in certain areas per 30-meter raster cell of a selected area. These plant communities are grouped based on similar environmental conditions, soil type, climate, and other natural factors. The different EVT lifeform categories can be grouped by name to provide simplified meaningful input to the model as follows: Tree—summation of all tree lifeforms; Shrub—summation of all shrub lifeforms; and Herb—summation of all herb lifeforms. The vegetation data may also be obtained from NASA GISS Global Distribution of Vegetation at 1°×1° Resolution, NASA LDAS North American Land Data Assimilation System (NLDAS) with Vegetation Class Datasets and Illustrations, NASA ORNL DAAC Vegetation Collection.

Vegetation height data can be extracted from the LANDFIRE 2022 Existing Vegetation Height (EVH) dataset, representing the average height of dominant vegetation per 30-meter raster cell. This dataset can be cropped to cover a selected area or state such as California, then overlaid on county grids to calculate the average height of dominant vegetation in each county. Vegetation height data can also be obtained from GLAD Global Forest Canopy Height or NASA ORNL DAAC Global Vegetation Height.

Leaf area index (LAI) data can be extracted from NOAA Moderate Resolution Imaging Spectroradiometer (MODIS) and modified in one or more embodiments by computing its value for each raster grid for an 8-day period throughout the year and later adjusted for a county level grid where the average LAI value is used. The LAI data can also be obtained from NASA NCEI Leaf Area Index or FAPAR CDR, NEO Leaf Area Index.

Normalized Difference Vegetation Index (NDVI) data can be extracted from NOAA NCEI Normalized Difference Vegetation Index CDR on a 0.05° by 0.05° global grid computed daily using satellite information. This is modified to fit a county level grid where the average NDVI is used to understand the health of vegetation in each county where unhealthy vegetation may be more prone to wildfire ignition. This data may also be obtained from USGS Landsat Normalized Difference Vegetation Index or NOAA MODIS Vegetation Index Products.

Tree Canopy Cover (TCC) data may be obtained from MRLC NLCD 2021 USFS Tree Canopy Cover at a 30-meter resolution derived from multi-spectral satellite imagery and other available information. This is modified to fit a county level grid where the average TCC is used to understand the percentage of TCC in each county. TCC may contribute to the spreading of wildfire as tree canopies often touch each other or are in close proximity such that fire in one can cause fire in an adjacent one. TCC data may also be obtained from GLAD Global 2010 Tree Cover (30-meter resolution).

Land Cover (LC) data may be obtained from MRLC NLCD 2021 at a 30 m resolution, derived from multiple sources, and systematically aligned over time to provide information on current and historical land cover changes. This dataset offers 16 main classifications that is further modified to combine some of the classifications as follows: LC_Developed—summation of categories 21 (Developed, Open Space), 22 (Developed, Low Intensity), 23 (Developed, Medium Intensity), and 24 (Developed, High Intensity); LC_Wetland—summation of categories 11 (Open Water), 90 (Woody Wetlands), and 95 (Emergent Herbaceous Wetlands); and LC_Low/no vegetation—summation of categories 31 (Barren Land), 71 (Grassland/Herbaceous), 81 (Pasture/Hay), and 82 (Cultivated Crops). This modification may then be fitted to a county level grid where the average LC is used to understand the trends of LC in each county. Land cover gives an indication of different types of fuel and their propensity for ignition that is present in an area of interest. LC data may also be obtained from GLAD Global Land Cover and Land Use Change, 2000-2020, NOAA Office of Coastal Management National Land Cover Database.

The infrastructure data 21F, which includes data of various facilities, is utilized to better understand human behaviors in relation to natural environments. In one or more embodiments, the facilities include hiking trails, campgrounds, park areas, and picnic grounds. The infrastructure data include road networks and transmission lines. Information on hiking trails, park areas, picnic grounds and campgrounds can be obtained from National Park Service (NPS) which identifies designated sites for camping, park boundaries, trail maps and picnicking within forested areas and national parks. Road network data can be acquired from the Harvard Dataverse, providing detailed mapping of transportation routes in and around natural areas. Road network data can also be obtained from NASA SEDAC Global Roads Open Access Data Set, US DOT Bureau of Transportation Statistics North American Roads Network. Transmission line information can be obtained from the Homeland Infrastructure Foundation-Level Data (HIFLD), which includes data on high-voltage power lines, or from Climate Mapping for Resilience & Adaptation, U.S. Electric Power Transmission Lines.

The environmental data 21G relates to properties or characteristics of climate zones, and ecological-regions. Climate zones can be categorized using the Köppen-Geiger classification system, with datasets generally available at a resolution of 0.5°×0.5° (approx. 50 km), which defines regions based on climate patterns from Climate Change & Infectious Diseases Group World Maps of Köppen-Geiger climate classification. Ecological-regions can be identified using data from the U.S. Environmental Protection Agency (EPA), which classifies ecological regions based on environmental and biological characteristics. Data for ecological regions can also be obtained from the National Hierarchical Framework of Ecological Units from the Forest Service. Some of this data may also be used for the climate data 21B.

The fire data 21H relates to a history of wildfires in various regions. The history may include date of the fire, size of the fire, cause of the fire, location of the fire, weather conditions before and during the fire, and fuel for the fire in non-limiting examples. Fire Data can be extracted from the sixth edition of Spatial wildfire occurrence data for the United States. This data includes discovery date, fire size, cause of fire and point location of wildfire data spanning from 1992-2020. The cause of fires can be updated to include the National Wildfire Coordinating Group (NWCG) wildfire-cause standard approved in August 2020. These fire data were aggregated after overlaying county level grid files to get the total number of fires. Fie data may also be obtained from USGS Combined wildfire datasets for the United States and certain territories, 1878-2019, VIIRS Active Fire, and MODIS Active Fire and Burned Area.

The input layer 21 may also include topography data, which relates to elevation data at points throughout an area or region of interest. Elevation data may be correlated to weather conditions or fuel loads that may be expected throughout the area or region of interest. The elevation data may be obtained from NASA's Shuttle Radar Topography Mission (SRTM30), providing high-resolution of 30 arc-seconds (˜1 km) global elevation information of Earth's terrain. The elevation data may also be obtained from Global Land One-kilometer Base Elevation of NOAA NCEI and USGS US Topo.

The modeling core 22 implements a software framework for processing the input data received from the input layer 21 of the wildfire software architecture 20. The input layer 21 includes data coming from several categories, including but not limited to weather, climate, sensors, human factors, fuel, infrastructure, environmental, vegetation, topographic, and historical wildfire data. These data are processed and combined at a common aggregation unit (e.g. grid cell, town, county, state) to create a dataset suitable for modeling. The modeling core 22 includes one or multiple AI or machine learning algorithms or models trained under different configurations. Training the AI or machine-learning algorithms with input data appropriate for obtaining selected outputs is inherently part of this disclosure. To find the best model configuration and converge towards optimal model hyper-parameters and variable selection, cross-validations are alternated with variable selection until optimal configuration is achieved. Once the optimal configuration is found for every model, the outputs are combined with techniques that include, but that are not limited to multiple linear regression or model stacking. Examples of outputs include (i) time-series of wildfire occurrences at multiple spatial and temporal scales, (ii) probability of wildfires in in each area, (iii) number of wildfires occurring in specific aggregation units, and (iv) warning of high fire risk for specific areas.

With respect to the AI or machine-learning models, in one or more embodiments, the processing unit 12 is configured to implement a neural network stored on a non-transitory medium. The neural network is trained to implement the AI and machine-learning models for performing aspects of the technology disclosed herein. The neural network includes an input layer for receiving input data and an output layer for outputting output data. Between the input layer and the output layer are hidden layers. Historic input data is used to train the neural network and the neural network makes a prediction or classification as output data based on current or real time input data. The current or real time input data may also be used to check or verify the accuracy of the prediction or classification. The neural network can be modified or updated by adjusting weights used in the various layers to improve the accuracy of the neural network. Accordingly, the current or real time input data can also be used to train the neural network in real time so that the neural network can provide the most up-to-date predictions or classifications. Continually training and updating the neural network is inherently included in the technology disclosed herein. It can be appreciated that in other embodiments AI or machine-learning algorithms that do not include a neural network may also be used.

This framework is scalable and adaptable to other climate zones and countries. Users of this model include, but are not limited to the U.S. Federal Government, States, utilities, fire departments, and stakeholders. Users will be able to use this model to assess wildfire risks for creating more refined mitigation plans, provide better lead time to affected people, implementation into a warning system that alerts about the percentage of confidence of the possibility of a wildfire event, determine the number of crews to combat this wildfire, or to drive public safety power shutoffs (PSPS).

The modeling core 22 includes a data processing section 22A, a data modeling section 22B, and a data post-processing section 22C. The data processing section 22A processes the input data using data cleaning to ensure uniformity, data manipulation for usability and data quality check for integrity of the collected data. The data used is extracted from multiple sources and refined using feature engineering, different algorithms and domain knowledge to create a new set of relevant features for training the model such as finding the max, mean, or other statistical parameters of the given data. Feature engineering is the selection and modification of raw datasets to create new features to aid in the improvement in wildfire prediction in the machine learning models. The output of the data processing section 22A includes relevant features of the input data to include statistical parameters of the input data. In general, the input data is condensed to the relevant features so as to improve the processing time in the data modeling section 22B.

The data modeling section 22B encompasses a wide range of techniques which include, but are not limited to statistical, machine learning, and artificial intelligence-based models. These models include but are not limited to Generalized Linear Model, Multiple Linear Regression Model, Decision Tree, Random Forest, Bayesian Models, eXtreme Gradient Boost, K-means Clustering, Logistic Regression, Naïve Bayes Classifier, Multilayer Perceptron, Support Vector Machine, K Nearest Neighbor, Hierarchical Clustering, Deep Neural Network, Generative Pre-trained Transformer, Convolutional Neural Networks, Long Short Term Memory Networks, Recurrent Neural Networks, Self-Organizing Maps, Deep Belief Networks, Autoencoders. In one or more embodiments, the eXtreme Gradient Boost model is used as a primary model. The other models in the above list of models are provided as alternatives that may be used in place of the eXtreme Gradient Boost (XGBoost) model. These algorithms can be modified to make predictions to provide similar outputs to those of the XGBoost algorithm. Each of these algorithms by themselves may be used for creating the wildfire predictions, wildfire density (i.e., number of wildfires per unit area) and wildfire ignition probability as well as other information of interest. Also, two or more of the algorithms can be used independently and their outputs cross-checked to determine accuracy and/or precision of the outputs.

A Generalized Linear Model (GLM) is a statistical model that helps understand and predict the relationships between variables (features). It allows one to see how changes in one variable affect another. GLMs are particularly useful for analyzing complex datasets, as they can handle different types of response variables and distributions.

A decision tree (DT) is a hierarchical tree structure used for modeling decisions and their possible outcomes. It includes nodes (decisions or splits based on feature values), branches (output of decisions), and leaves (final outputs or predictions). DT also incorporates probabilities to show the likelihood of different outcomes occurring.

Random Forest (RF) is a supervised learning algorithm that includes multiple decision trees that work together to improve prediction accuracy and reliability. By aggregating the predictions of individual trees, the use of RF reduces the risk of overfitting and enhances overall model performance.

Gradient Boosting (GB) is an algorithm that builds an ensemble of weak decision tree models to improve predictive performance for both regression and classifications. It works by sequentially training each tree to correct the errors made by the previous trees to improve overall model prediction.

eXtreme Gradient Boosting (XGBoost) is a machine learning algorithm that builds an ensemble of decision trees in a sequential manner, where each tree is trained to correct the errors of the previous trees. It also assigns weights to features based on their importance in making predictions to enhance the overall predictions of the model. Incremental learning is used with XGBoost to allow the model to update its knowledge without the need to retrain from the beginning. With respect to the technology disclosed herein, the XGBoost, is a machine learning algorithm based on gradient boosting that builds an ensemble of decision trees. Decision trees are a supervised machine learning model that works by iteratively splitting the data into subsets based on characteristics of the data that are used by the model to make predictions (feature values), creating a tree-like structure with decision nodes and leaf nodes. Decision nodes are where the trees are split based on a specific feature and leaf nodes are the predicted values in the end after the decisions are made. Multiple of these decision trees, ones with the best performance, are combined to create a stronger model known as an ensemble model. The model is then trained by iteratively adding trees to minimize the loss function that balances accuracy and model complexity. Cross-validation is used to evaluate the performance of the model and select optimal hyperparameters, such as the number of trees, learning rate, tree depth, etc. Once trained, the XGBoost model generates predictions for wildfire predictions, wildfire density and wildfire ignition probability. These outputs are later visualized as time series, tables and spatial maps.

Support Vector Machine (SVM) uses a set of supervised learning algorithms that can be used for classification, regression, and outlier detection. SVM works by finding the optimal hyperplane that separates different classes in the feature space, maximizing the margin between them. A hyperplane is a decision boundary that separates data points into different classes.

k-Nearest Neighbors (kNN) is an algorithm used for classification and regression that assumes similar data points are located close to each other in the feature space. When making predictions for a new data point, kNN identifies the ‘k’ closest training examples and decides based on this.

Convolutional Neural Networks (CNNs) are artificial intelligence models designed to analyze visual data. They include several layers, each with a specific role. One layer, called a convolutional layer, scans the input in small sections to detect basic patterns in the data, like edges or textures. Another layer, known as a pooling layer, reduces the size of this information by focusing on the most important features to simplify the data. The final layers process this information further to make predictions.

Long Short-Term Memory Networks (LSTMs) are artificial intelligence models designed to understand and predict sequences in data. They feature memory cells that store information over time, to make informed decisions based on past context. LSTMs also include gates that determine what information to keep or forget, helping to reduce noise and optimize model predictions.

The data post-processing section 22C includes hyperparameter tuning, cross validation, and feature selection for model optimization and multiple linear regressions and model stacking for model output combination for improved models.

For optimization, hyper parameter tuning is used to identify the best set of parameters that contribute to the way the models handle data. This ensures that the model is trained under the best possible conditions, improving its accuracy and robustness. In one or more embodiments, for simplicity and lower computation time, grid search is used to identify the best hyperparameters. Grid search defines a grid of hyperparameters and evaluates all possible combinations for the model to yield the best results for the given models. Random Search or Bayesian Optimization may also be used.

The leave-one-out cross-validation (LOOCV), a type of k-fold validation, can be employed to thoroughly evaluate model capabilities by providing insights into its feasibility. By using LOOCV, the model is trained on a subset of the dataset for each iteration, thereby minimizing the risk of information leakage during training and improving its ability to generalize to unseen data. K-Fold Cross-Validation, Stratified K- Fold Cross-Validation, Time Series Cross-Validation, or Group K-Fold Cross-Validation may also be used to evaluate model capabilities.

Supervised variable selection may be used based on the understanding of the core variables that contribute to wildfires to find other variables that contribute to the understanding of these fires. This reduces the number of features, further simplifying the model and increasing interpretation and reducing computation time. Forward variable selection, backward variable elimination, stepwise selection, or correlation-based feature selection may also be used for reducing the number of features.

To improve prediction accuracy, once the optimal configuration is found for every model, the outputs are combined with techniques that include, but that are not limited to multiple linear regression or model stacking. Multiple linear regression is a statistical method that treats the outputs of different models as independent variables. It aims to find the best weighted combination of these predictions to optimize overall results while minimizing overall errors in the model predictions. Model stacking is an ensemble learning technique in which multiple base models are trained to make predictions. A combination model is then trained on the outputs of these base models to combine their predictions. This combination model learns to weigh the contributions of each base model based on the reliability of their outputs, allowing it to optimize the final predictions and improve overall model performance.

Outputs from the data post-processing section 22C are provided to model outputs 23. The model outputs include wildfire ignition predictions 23A, wildfire ignition density 23B, and wildfire ignition probability 23C. For example, the model outputs 23 may include, but are not limited to, a time-series of wildfire occurrences at multiple spatial and temporal scales for each area of interest and may include (i) probability of wildfires in in each area, (ii) number of wildfires occurring in specific aggregation units, and (iii) warning of high fire risk for specific areas. Any of these outputs may have a level of confidence for the prediction. The time series may include, but are not limited to, daily, sub-daily, hourly or sub-hourly predictions for (i) the probability of wildfire occurrence in a specific aggregation unit, (ii) the projected number of wildfires in a specific aggregation unit. Wildfire occurrence probabilities and counts may be broken down into probabilities and counts of fire occurrences by different causes. Users can select the area of their choice for these forecasts.

Examples of day-ahead time series forecasts include, but are not limited to, (i) the hourly number of total wildfires expected to occur in a specific region; (ii) the hourly probability of having wildfires in a specific region; (iii) the hourly probability of having wildfires caused by transmission lines in a specific county; (iv) the total expected hourly occurrence of human-caused wildfires in a specific town. For time series, the x-axis shows temporal increments, and the y-axis shows the predicted number of fires, or the predicted probability for each hour.

The model outputs 23 may also include point forecasts that include, but are not limited to, daily, sub-daily, hourly or sub-hourly predictions for the probability of wildfire occurrence within a certain distance from a specific location. Wildfire occurrence probability may be broken down into probabilities of fire occurrences by different causes. Users can select the location of their choice for these forecasts. Examples of day-ahead point forecasts include but are not limited to (i) the hourly probability of having wildfires in a 25 miles radius from a specific location and (ii) the hourly probability of human-caused wildfires within 3 miles of a critical facility.

The model outputs 23 may also include risk forecasts. Risk forecasts may include but are not limited to (i) predictions of wildfire risk for specific areas at different temporal scales, (ii) wildfire return periods, and (iii) risk of wildfires above a specific threshold, which may trigger an alert. Examples include (i) future wildfire risk map (e.g. wildfire risk map in 2030, to be used by an insurance company to determine insurance rate forecasts, or to be used by a business planner to determine potential future insurance hikes assuming that higher risk correlates to higher insurance rates), (ii) day-ahead wildfire risk for a specific county that can trigger a National Weather Service Red Flag Warning.

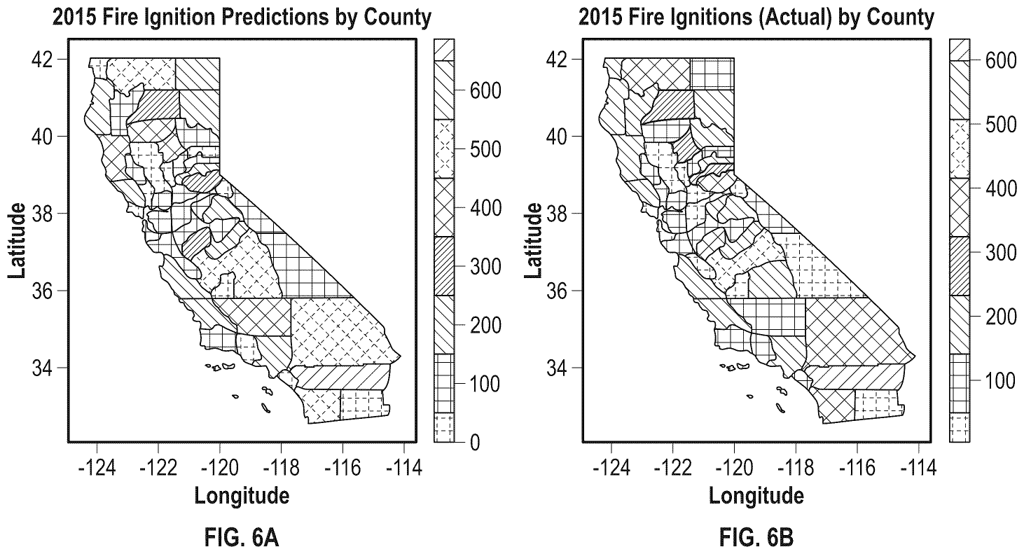

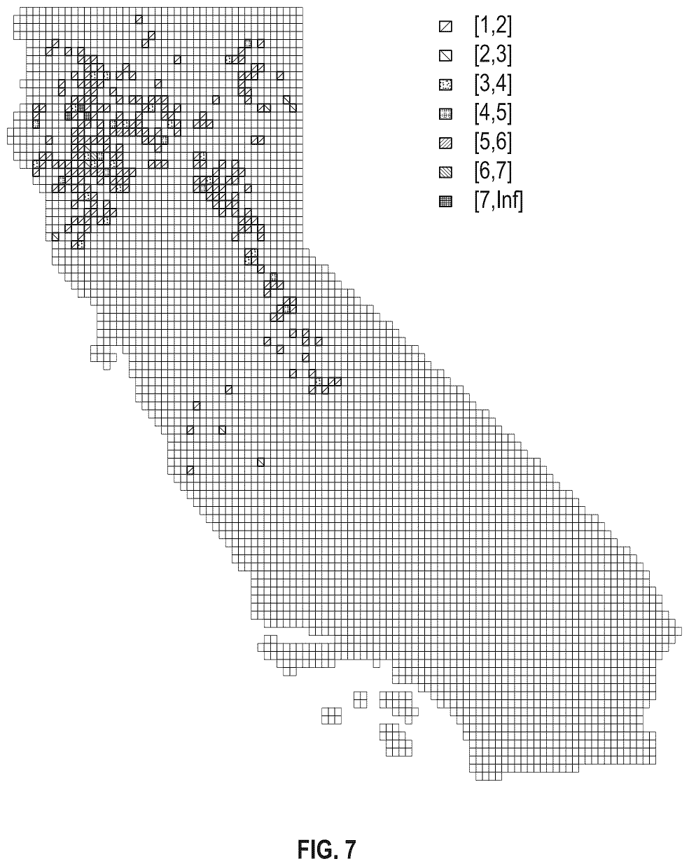

The model outputs 23 may also include spatial maps 25B as part of visualizations 25. Spatial maps 25B include, but are not limited to, color coded maps of risk levels for each aggregation unit or grid cell, maps showing total expected or forecasted number of wildfires in a specific day, maps of wildfire probabilities, maps of historical, current, or future estimates of wildfire ignitions or wildfire ignition risk, return periods, maps of high-risk areas triggering alerts. Maps 25B may be color-coded, with an example of color palette ranging from red (highest risk) to green (lowest risk). There can be a description in a legend of each of the color levels explaining the type of wildfire risks to which the area of interest may be exposed. FIGS. 6 and 7 illustrate examples of maps that can be output to a user.

For the spatial maps 25B, in one embodiment the format is a shapefile (.shp). This format allows for users to zoom in and out of their areas of interest and explore specific regions to see the predicted impacts of wildfires. These maps can also utilize color gradients and symbols that allow users to highlight also the conditions and their values that contribute to wildfires, such as temperature, precipitation, or wind speed. Additionally, interactive features can allow users to click on specific areas to get sliding views of a 1-year, 5-year, and 10-year historical comparisons of wildfire risk, for example, contingent upon the availability of data. Other types of formats for spatial maps may also be used.

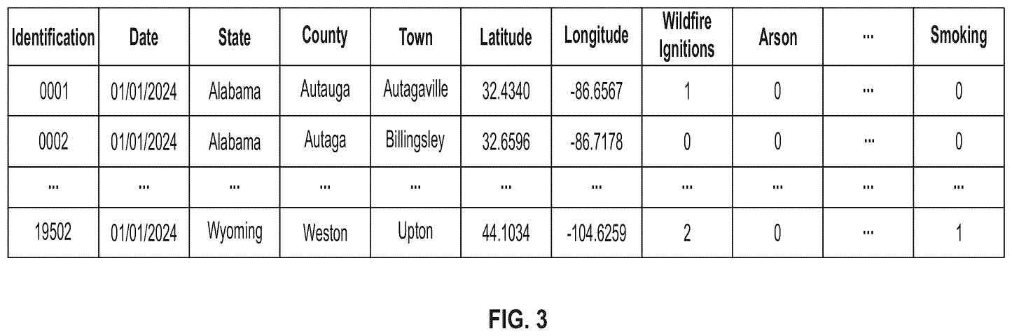

The model outputs 23 may also include tabulated data. Tabulated data include, but are not limited to (i).csv files of predicted wildfires at a 30-meter spatial resolution and daily temporal resolution with corresponding grid IDs for aggregation to different spatial and temporal resolution needed, (ii).txt files of predicted wildfires at a 30-meter spatial resolution and hourly temporal resolution with corresponding grid IDs for dissemination of larger quantities of data, and (iii).shp files of predicted wildfire spatial points with descriptive information on the level on confidence in the model prediction and geographic distribution. Tabulated data provide users with flexibility to utilize and synthesis wildfire prediction that best fit their needs. Other types of file formats may also be used to present tabulated data. FIG. 3 illustrates an example of tabulated data that can be provided as an output to a user.

Outputs from the model outputs 23 are provided to notification systems 24. Notification outputs or alerts of the notification systems 24 may be triggered regularly (e.g. by cronjob software) or by exceedance of specific thresholds over specific areas. Notifications include, but are not limited to, emails 24B, social media on websites 24C and alerts by text message 24A. The emails 24B can be sent to users, including, but not limited to, local National Weather Service offices, utility companies to coordinate PSPS, or fire departments. Content of emails can include, but is not limited to, time series, risk forecasts, spatial maps, point data, or model predictions along with an associated level of confidence. Priority of the alerts can be sent to offices and departments in closer proximity to the fires and later sent to the different offices in the given state(s) affected. Text message 24A alerts can be distributed as an emergency alert system to people and entities in the surrounding susceptible areas. The text message 24A can include information on the probability of any or a number of fires in the area, the risk level along with a color-coded scale and explanation, and the range of the number of fires in the given area. Social media alerts can be sent to the social media platforms of utilities, fire stations, and national weather services to provide them with information of the current conditions, the probability of fires, the total predicted number of fires and the areas more susceptible to experiencing these fires. Other media 24D (e.g., direct connections or telephone calls) may also be used to send notifications or alerts.

The visualizations 25 also include animations 25C. Using the color-coded risk level of fires, an animation can be created to show the risk posed to humans and their properties in each risk level. This animation can show an example of a home with “perfect weather” conditions. For each risk level of fire, the skies can show the different conditions one might see in such a case along with the impact it can have on their assets (e.g. cars, homes, etc.) and themselves (e.g. lack of visibility, difficulty breathing, etc.). The user can add other elements such as the key factors found to contribute to wildfires to see how it increases or decreases the impact of wildfires. Alternatively or in addition, the animations 25C can include animations showing ignition risk over time. For example, animated maps may be used to show via color-coded grid cells how ignition risk changes over time. This information serves to better inform people of signs to look out for, what they can do and contribute to providing them with ways to help mitigate conditions that exacerbate the impacts of fires.

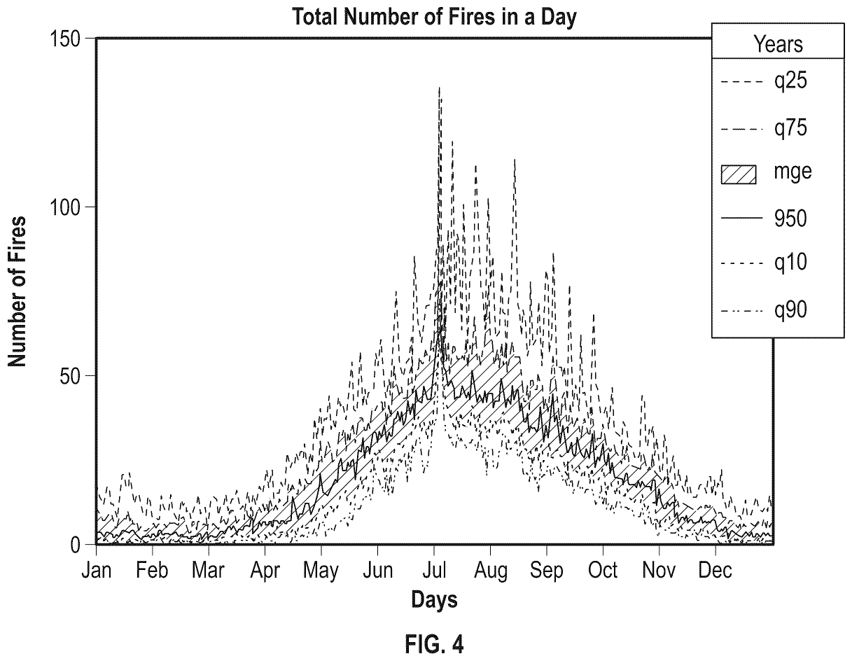

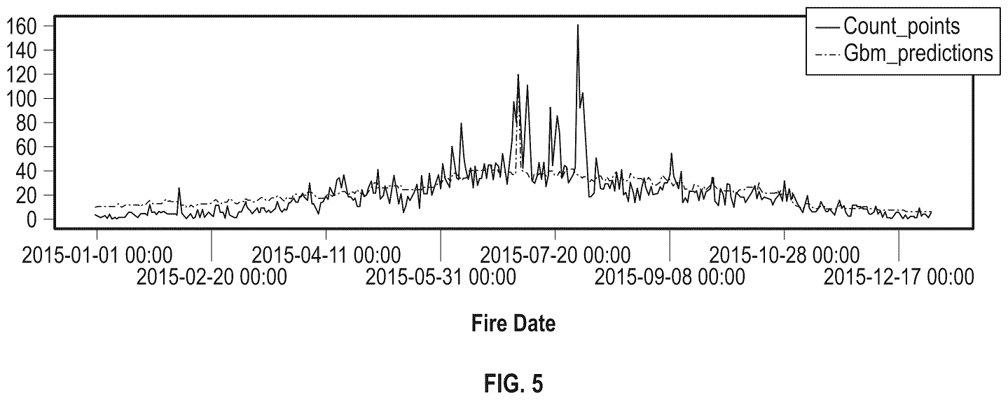

The visualizations 25 also include a time series 25A. For time-series forecasts 25A, the default format for the results can be distributed as a Portable Document Format (PDF) file. This format allows for the representation of the forecasts as a time-series graphs, along with tables that visualize trends over time, making it easier to understand numerical fluctuations and patterns in the data. Additionally, the PDF can include annotations and summaries to highlight key insights to provide the users with implications of this forecast along with the level of confidence of the predictions. FIGS. 4 and 5 illustrate examples of time-series graphs.

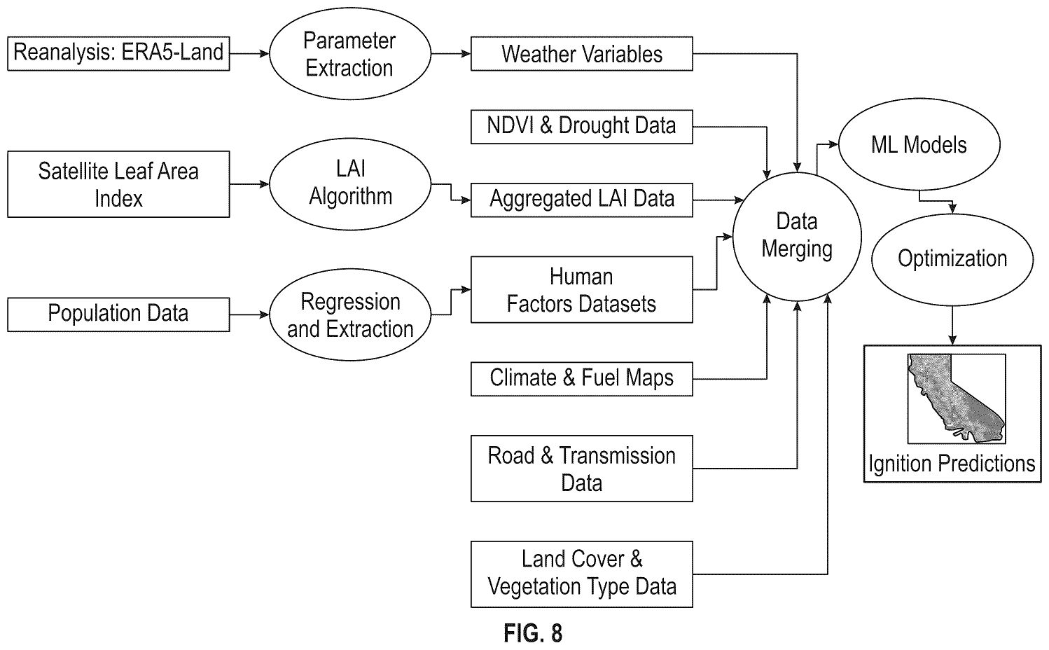

FIG. 8 depicts aspects of interactions between various software modules to produce wildfire ignition predictions. In the embodiment of FIG. 8, certain databases are processed to extract appropriate or relevant data that is useful for the input layer 21. For example, appropriate parameters are extracted from the Reanalysis: ERA5-Land database and provided to the weather data 21A. Appropriate leaf area index (LAI) parameters are extracted from the Satellite Leaf Area Index using a LAI algorithm and are provided to Aggregated LAI Data in the input layer 21. Appropriate population parameters are extracted from a population database using a regression and extraction algorithm and provided to the human factors data 21C. The modeling core 22 then merges the input data from the input layer 21 using a data merging algorithm to provide merged data. The modeling core 22 then creates machine-learning (ML) models such as for example with neural networks using the merged data. The modeling core 22 then optimizes the ML models and provides ignition predictions. The ignition predictions may include the probability of wildfire ignition at selected locations, a probable trajectory of a wildfire if ignited, and an intensity of a wildfire if ignited in non-limiting locations embodiments. The ignition predictions can be used to send alert notifications and initiate proactive measures to prevent ignition of a wildfire at a high probability location. Alert notifications can include activating sirens or speakers in one or more local areas that warn the populace of the high probability of a wildfire ignition or to have the populace evacuate the area if a wildfire has already ignited. Prevention measures may include turning off power in the high probability areas or dispatching fire crews to remove fuel from the high probability areas.

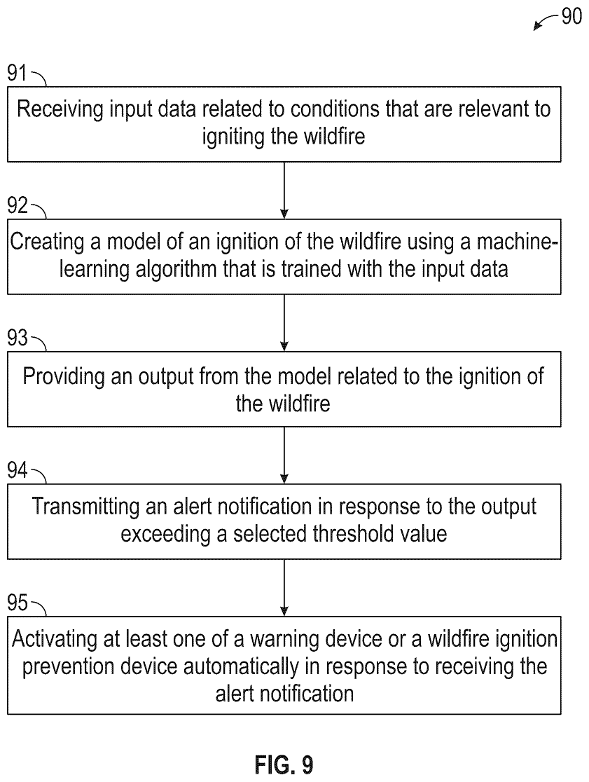

FIG. 9 is a flowchart for a method 90 for at least one of warning of a wildfire potential or preventing ignition of a wildfire. Block 91 calls for receiving input data related to conditions that are relevant to igniting the wildfire. Non-limiting embodiments of the input data include weather data, climate data, multi-sensor data, human factors data, fuel data, infrastructure data, environmental data, or historical fire data.

Block 92 calls for creating a model of an ignition of the wildfire using a machine-learning algorithm that is trained with the input data.

Block 93 calls for providing an output from the model related to the ignition of the wildfire. Non-limiting embodiments of the output include a risk of ignition, an ignition prediction, an ignition density, and an ignition probability.

Block 94 calls for transmitting an alert notification in response to the output exceeding a selected threshold value. In one or more embodiments, the alert message is a warning transmitted via a text message, an email message, a website, an internet virtual meeting environment, telephone, radio, or television.

Block 95 calls for activating at least one of a warning device or a wildfire ignition prevention device automatically in response to receiving the alert notification. In one or more embodiments, the warning device includes loudspeakers or sirens disposed throughout an area of interest affected by the alert notification. The loudspeaker may emit vocal warning information or a selected sound associated with a warning. The siren is configured to emit a selected sound associated with a warning. In one or more embodiments, the wildfire ignition prevention device is a remotely operated switch disposed in a power grid supplying electricity and configured to disconnect electricity to the area of interest affected by the alert notification.

The technology disclosed herein provides several advantages. One advantage is that the technology improves the accuracy of predicting the occurrence of wildfires in a selected area of interest to include a probability or risk of wildfire ignition and a density of wildfire ignitions. Another advantage is that the technology can enable reductions in the time it takes for a populace in an area of interest to be warned of a potential wildfire ignition. Yet another advantage is that the technology enables improvements in the time for disconnecting power to an area of interest in response to a high probability of a wildfire ignition in that area of interest. Yet another advantage is that the technology can provide the sending of alert signals automatically and thus not be reliant on personnel for sending them. This avoids delays due to the personnel not being available, such being on a break, when the risk of a wildfire reaches a dangerous level.

The technology is particularly useful for population centers adjacent to or in areas prone to wildfires and having limited means of egress. The technology provides for increased warning times to enable the population to have adequate time to evacuate the area. This can be accomplished by lowering the threshold level at which the alert signal is sent. In one example, the technology can be applied to a national park. If the risk of a wildfire at the park or areas adjacent to the park exceed the threshold level, then the alert signal would give park visitors adequate time to exit the park. Also, fire officials at the park can be placed on standby or alert in anticipation of a wildfire ignition and thus be able to respond quicker should an actual wildfire ignition occur.

In support of the teachings herein, various analysis components may be used, including a digital and/or an analog system. For example, the wildfire ignition and mitigation system components 10 including the processing unit 12 and any sensors providing input data may include digital and/or analog systems. The system may have components such as a processor, storage media, memory, input, output, communications link (wired, wireless, optical or other), user interfaces (e.g., a display or printer), software programs, signal processors (digital or analog) and other such components (such as resistors, capacitors, inductors and others) to provide for operation and analyses of the apparatus and methods disclosed herein in any of several manners well-appreciated in the art. It is considered that these teachings may be, but need not be, implemented in conjunction with a set of computer executable instructions stored on a non-transitory computer readable medium, including memory (ROMs, RAMs), optical (CD-ROMs), or magnetic (disks, hard drives), or any other type that when executed causes a computer to implement the method of the present invention. These instructions may provide for equipment operation, control, data collection and analysis and other functions deemed relevant by a system designer, owner, user or other such personnel, in addition to the functions described in this disclosure.

All statements herein reciting principles, aspects, and embodiments of the disclosure, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

Various other components may be included and called upon for providing for aspects of the teachings herein. For example, additional materials, combinations of materials and/or omission of materials may be used to provide for added embodiments that are within the scope of the teachings herein. Adequacy of any particular element for practice of the teachings herein is to be judged from the perspective of a designer, manufacturer, seller, user, system operator or other similarly interested party, and such limitations are to be perceived according to the standards of the interested party.

In the disclosure hereof any element expressed as a means for performing a specified function is intended to encompass any way of performing that function including, for example, a) a combination of circuit elements and associated hardware which perform that function or b) software in any form, including, therefore, firmware, microcode or the like as set forth herein, combined with appropriate circuitry for executing that software to perform the function. Applicants thus regard any means which can provide those functionalities as equivalent to those shown herein. No functional language used in claims appended herein is to be construed as invoking 35 U.S.C. § 112 (f) interpretations as “means-plus-function” language unless specifically expressed as such by use of the words “means for” or “steps for” within the respective claim.

When introducing elements of the present invention or the embodiment(s) thereof, the articles “a,” “an,” and “the” are intended to mean that there are one or more of the elements. Similarly, the adjective “another,” when used to introduce an element, is intended to mean one or more elements. The terms “including” and “having” are intended to be inclusive such that there may be additional elements other than the listed elements. The conjunction “or” when used with a list of at least two terms is intended to mean any term or combination of terms. The conjunction “and/or” when used between two terms is intended to mean both terms or any individual term. The term “configured” relates one or more structural limitations of a device that are required for the device to perform the function or operation for which the device is configured. The term “exemplary” is not intended to be construed as a superlative example but merely one of many possible examples.

The flow diagram depicted herein is just an example. There may be many variations to this diagram or the steps (or operations) described therein without departing from the scope of the invention. For example, operations may be performed in another order or other operations may be performed at certain points without changing the specific disclosed sequence of operations with respect to each other. All of these variations are considered a part of the claimed invention.

The technology disclosed herein may be practiced in at least some embodiments with a set of elements as claimed or set forth. In some other embodiments, the technology may be enhanced by including additional elements to provide additional benefits.

While one or more embodiments have been shown and described, modifications and substitutions may be made thereto without departing from the scope of the invention. Accordingly, it is to be understood that the present invention has been described by way of illustrations and not limitations.

It will be recognized that the various components or technologies may provide certain necessary or beneficial functionality or features. Accordingly, these functions and features as may be needed in support of the appended claims and variations thereof, are recognized as being inherently included as a part of the teachings herein and a part of the invention disclosed.

While the invention has been described with reference to exemplary embodiments, it will be understood that various changes may be made and equivalents may be substituted for elements thereof without departing from the scope of the invention. In addition, many modifications will be appreciated to adapt a particular instrument, situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A system for at least one of warning of a possible wildfire or preventing a wildfire ignition in a selected area of interest, the system comprising:
a processor configured to execute instructions stored on a non-transitory medium, the instructions implementing a method comprising:
receiving input data related to conditions that are relevant to igniting a wildfire in the selected area of interest;
creating a model of a possible wildfire ignition in the selected area of interest using an artificial intelligence algorithm that is trained with the input data;
providing an output from the model related to the possible wildfire ignition;
transmitting an alert notification automatically in response to the output exceeding a selected threshold value;
at least one of a warning device or a wildfire ignition prevention device configured to be automatically activated in response to receiving the alert notification.

2. The system according to claim 1, wherein the input data comprises at least one of weather data, climate data, multi-sensor data, human factors data, fuel data, infrastructure data, environmental data, and historical fire data.

3. The system according to claim 1, wherein the output comprises at least one of risk of ignition, an ignition prediction, an ignition density, an ignition probability, or a geographic distribution of possible ignitions.

4. The system according to claim 1, wherein the warning device comprises at least one of a loudspeaker or siren disposed in the selected area of interest.

5. The system according to claim 1, wherein the warning device comprises a radio or television network configured to automatically broadcast an emergency message.

6. The system according to claim 1, wherein the wildfire ignition prevention device comprises a remote-controlled switch in communication with the processor and configured to disconnect power in the selected area of interest in response to receiving the alert notification.

7. The system according to claim 1, wherein the alert notification comprises a warning message and is sent via at least one of a text message, an email message, a website, an internet virtual meeting environment, telephone, radio, or television.

8. The system according to claim 1, wherein the alert notification comprises a visualization of the output, the visualization comprising at least one of a time-series graph, a map illustrating risk or potential wildfire ignitions, an animation, or a data table.

9. A non-transitory computer-readable medium comprising instructions for at least one of warning of a possible wildfire or preventing a wildfire ignition in a selected area of interest that when executed by a processor implements a method comprising:
receiving input data related to conditions that are relevant to igniting a wildfire in the selected area of interest;
creating a model of a possible wildfire ignition in the selected area of interest using an artificial intelligence algorithm that is trained with the input data;
providing an output from the model related to the possible wildfire ignition; and
transmitting an alert notification to at least one of a warning device or a wildfire ignition prevention device in response to the output exceeding a selected threshold value, the at least one of the warning device and the wildfire ignition prevention device being configured to be automatically activated in response to receiving the alert notification.

10. The non-transitory computer-readable medium according to claim 9, wherein the input data comprises at least one of weather data, climate data, multi-sensor data, human factors data, fuel data, infrastructure data, environmental data, and historical fire data.

11. The non-transitory computer-readable medium according to claim 9, wherein the output comprises at least one of risk of ignition, an ignition prediction, an ignition density, or an ignition probability.

12. The non-transitory computer-readable medium according to claim 9, wherein the warning device comprises at least one of a loudspeaker or siren disposed in the selected area of interest.

13. The non-transitory computer-readable medium according to claim 9, wherein the warning device comprises a radio or television network configured to automatically broadcast an emergency message.

14. The non-transitory computer-readable medium according to claim 9, wherein the wildfire ignition prevention device comprises a remote-controlled switch in communication with the processor and configured to disconnect power in the selected area of interest in response to receiving the alert notification.

15. A system for at least one of warning of a possible wildfire or preventing a wildfire ignition in a selected area of interest, the system comprising:
a processor configured to execute instructions stored on a non-transitory medium, the instructions implementing a method comprising:
receiving input data related to conditions that are relevant to igniting a wildfire in the selected area of interest;
creating a model of a possible wildfire ignition in the selected area of interest using an artificial intelligence algorithm that is trained with the input data;
providing an output from the model related to the possible wildfire ignition, the output comprising a visualization of output data;
transmitting an alert notification in response to the output exceeding a selected threshold value;
a sensor in communication with the processor and disposed in the selected area of interest, the sensor being configured to sense an environmental parameter; and
at least one of a warning device or a wildfire ignition prevention device configured to be automatically activated in response to receiving the alert notification.

16. The system according to claim 15, wherein the environmental parameter comprises at least one of temperature, dew point temperature, dew point depression, soil moisture, relative humidity, rainfall, wind speed and direction, wind gust speed, smoke amount, or solar radiation.

17. The system according to claim 15, wherein the visualization of output data comprises at least one of a time-series graph, a map, an animation, or a data table.
